(19) United States
(12) Patent Application Publication
(10) Pub. No.: US 2014/0373877 A1
(43) Pub. Date: Dec. 25, 2014

(54) LIQUID PROCESSING APPARATUS AND LIQUID PROCESSING METHOD

(71) Applicant: Tokyo Electron Limited, Tokyo (JP)

(72) Inventors: Shigehisa Inoue, Kumamoto (JP); Daisuke Nakayama, Kumamoto (JP); Katsufumi Matsuki, Kumamoto (JP); Takuro Masuzumi, Kumamoto (JP); Yuki Yoshida, Kumamoto (JP); Meitoku Aibara, Kumamoto (JP); Hiromi Kiyose, Kumamoto (JP); Takashi Uno, Kumamoto (JP); Hirotaka Maruyama, Kumamoto (JP); Kazuya Koyama, Kumamoto (JP); Takashi Nakazawa, Kumamoto (JP)

(21) Appl. No.: 14/297,723

(22) Filed: Jun. 6, 2014

(30) Foreign Application Priority Data
Jun. 21, 2013 (JP) 2013-130883
Apr. 18, 2014 (JP) 2014-086639

(51) Int. Cl. B08B 3/02; H01L 21/67

(52) U.S. Cl. CPC B08B 3/02; H01L 21/67051
USPC 134/26; 134/99.1

(57) ABSTRACT

Disclosed are a liquid processing apparatus and a liquid processing method in which a substrate is processed by a processing liquid in the form of liquid droplets. The liquid processing apparatus includes: a first processing liquid ejecting unit configured to eject a first processing liquid in a form of liquid droplets which contains pure water toward the surface of the substrate; and a second processing liquid ejecting unit configured to eject a second processing liquid as a continuous liquid stream toward the surface of the substrate processed by the first processing liquid in the form of the liquid droplets. The second processing liquid inverts a zeta potential on the surface of the substrate into a negative zeta potential.

### CROSS-REFERENCE TO RELATED APPLICATIONS

This application is based on and claims priority from Japanese Patent Application Nos. 2013-130883, and 2014-086639 filed on Jun. 21, 2013, and Apr. 18, 2014, respectively, with the Japan Patent Office, the disclosures of which are incorporated herein in their entireties by reference.

### TECHNICAL FIELD

The present disclosure relates to a liquid processing apparatus and a liquid processing method in which a substrate is processed by a processing liquid in the form of liquid droplets which contains pure water.

### BACKGROUND

When, for example, a semiconductor component or a flat panel display is manufactured, a liquid processing apparatus has conventionally been used to perform various processings such as cleaning or etching on a substrate such as, for example, a semiconductor wafer or a liquid crystal substrate.

For example, in the liquid processing apparatus configured to clean a substrate, an SC-1 (Standard Clean 1) liquid (a mixed solution of hydrogen peroxide, ammonium hydroxide, and pure water) is supplied toward the substrate which rotates, and the surface of the substrate is processed by the cleaning liquid. Then, a mixed fluid of pure water and nitrogen gas is sprayed from a two-fluid nozzle toward the substrate, and the surface of the substrate is processed by the pure water in the form of liquid droplets. Then, pure water is supplied toward the substrate, and the surface of the substrate is processed by the pure water. Finally, the substrate is rotated at a high speed so that the pure water is shaken off from the surface of the substrate to dry the surface of the substrate.

In this manner, in a conventional liquid processing apparatus, the surface of the substrate is processed by pure water in the form of liquid droplets by using a two-fluid nozzle so that the surface of the substrate may be sufficiently processed even if a circuit pattern formed on the surface of the substrate is miniaturized (see, e.g., Japanese Patent Laid-open Publication No. 2005-46737).

### SUMMARY

The present disclosure provides a liquid processing apparatus including: a first processing liquid ejecting unit configured to eject a first processing liquid in a form of liquid droplets which contains pure water toward a surface of a substrate; and a second processing liquid ejecting unit configured to eject a second processing liquid as a continuous liquid stream toward the surface of the substrate processed by the first processing liquid in the form of the liquid droplets. The second processing liquid inverts a zeta potential on the surface of the substrate into a negative zeta potential.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a liquid processing apparatus.

FIG. 2 is a vertical cross-sectional view illustrating the liquid processing apparatus.

FIG. 3 is an explanatory view illustrating an operation of the liquid processing apparatus (a substrate receiving process).

FIG. 4 is an explanatory view illustrating an operation of the liquid processing apparatus (a liquid droplet processing process).

FIG. 5 is an explanatory view illustrating an operation of the liquid processing apparatus (a zeta potential inverting process).

FIG. 6 is an explanatory view illustrating an operation of the liquid processing apparatus (a rinsing process).

FIG. 7 is an explanatory view illustrating an operation of the liquid processing apparatus (a drying process).

FIG. 8 is an explanatory view illustrating an operation of the liquid processing apparatus (a substrate delivery process).

FIGS. 9A to 9E are explanatory views illustrating a zeta potential on a substrate surface.

FIGS. 10A and 10B are flow charts illustrating a substrate processing method.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The inventors found that when a surface of a substrate is processed by an SC-1 liquid and then processed by pure water in the above described conventional liquid processing apparatus, particles attached on the surface of the substrate prior to the processing may be removed, but particles in the atmosphere are newly attached on the surface of the substrate during the processing.

An aspect of the present disclosure is to provide a liquid processing apparatus including: a first processing liquid ejecting unit configured to eject a first processing liquid in a form of liquid droplets which contains pure water toward a surface of a substrate; and a second processing liquid ejecting unit configured to eject a second processing liquid as a continuous liquid stream toward the surface of the substrate processed by the first processing liquid in the form of the liquid droplets. The second processing liquid inverts a zeta potential on the surface of the substrate into a negative zeta potential.

The second processing liquid ejecting unit ejects the second processing liquid toward the surface of the substrate right after the surface of the substrate is processed by the first processing liquid in the form of the liquid droplets.

The liquid processing apparatus further includes an SC-1 liquid ejecting unit configured to eject an SC-1 liquid toward the surface of the substrate, in which the first processing liquid ejecting unit ejects the first processing liquid in the form of the liquid droplets after the SC-1 liquid is ejected from the SC-1 liquid ejecting unit toward the surface of the substrate.

Pure water added with carbon dioxide is used as the first processing liquid, and an SC-1 liquid is used as the second processing liquid.

As the substrate, a substrate having a surface formed with a silicon nitride film is used.

The liquid processing apparatus further includes a third processing liquid ejecting unit configured to eject a third processing liquid as a continuous liquid stream toward the surface of the substrate processed by the first processing liquid in the form of the liquid droplets. The third processing liquid discharges electric charges electrified on the substrate.

Pure water added with carbon dioxide is used as the third processing liquid, and an SC-1 liquid is used as the second processing liquid.

Another aspect of the present disclosure is to provide a method of performing a liquid processing on a substrate by using a liquid processing apparatus which includes a first processing liquid ejecting unit configured to eject a first processing liquid in a form of liquid droplets which contains pure water toward a surface of the substrate, and a second processing liquid ejecting unit configured to eject a second processing liquid as a continuous liquid stream to the surface of the substrate, the method including: processing the surface of the substrate by the first processing liquid in the form of the liquid droplets which contains the pure water; and ejecting the second processing liquid from the second processing liquid ejecting unit to the surface of the substrate to process the surface of the substrate. The second processing liquid inverts a zeta potential on the surface of the substrate into a negative zeta potential.

The surface of the substrate is processed by the second processing liquid right after the surface of the substrate is processed by the first processing liquid in the form of the liquid droplets.

The surface of the substrate is processed by an SC-1 liquid before the surface of the substrate is processed by the first processing liquid in the form of the liquid droplets.

Pure water added with carbon dioxide is used as the first processing liquid, and an SC-1 liquid is used as the second processing liquid.

As the substrate, a substrate having a surface formed with a silicon nitride film is used.

After the surface of the substrate is processed by the first processing liquid in the form of the liquid droplets, the surface of the substrate is processed by a continuous liquid stream of a third processing liquid, and then is processed by the second processing liquid. The third processing liquid discharges electric charges electrified on the substrate.

Pure water added with carbon dioxide is used as the third processing liquid, and an SC-1 liquid is used as the second processing liquid.

Pure water added with carbon dioxide is used as the first processing liquid. The surface of the substrate is processed by an SC-1 liquid before the surface of the substrate is processed by the first processing liquid in the form of the liquid droplets. In addition, the surface of the substrate is processed by pure water added with carbon dioxide as a continuous liquid stream after the surface of the substrate is processed by the first processing liquid in the form of the liquid droplets, and the second processing liquid.

In the present disclosure, particles in the atmosphere may be suppressed from being newly attached on the surface of the substrate, and thus, the processing of the substrate may be sufficiently performed.

Hereinafter, a specific configuration of a liquid processing apparatus and a liquid processing method according to the present disclosure will be described with reference to drawings.

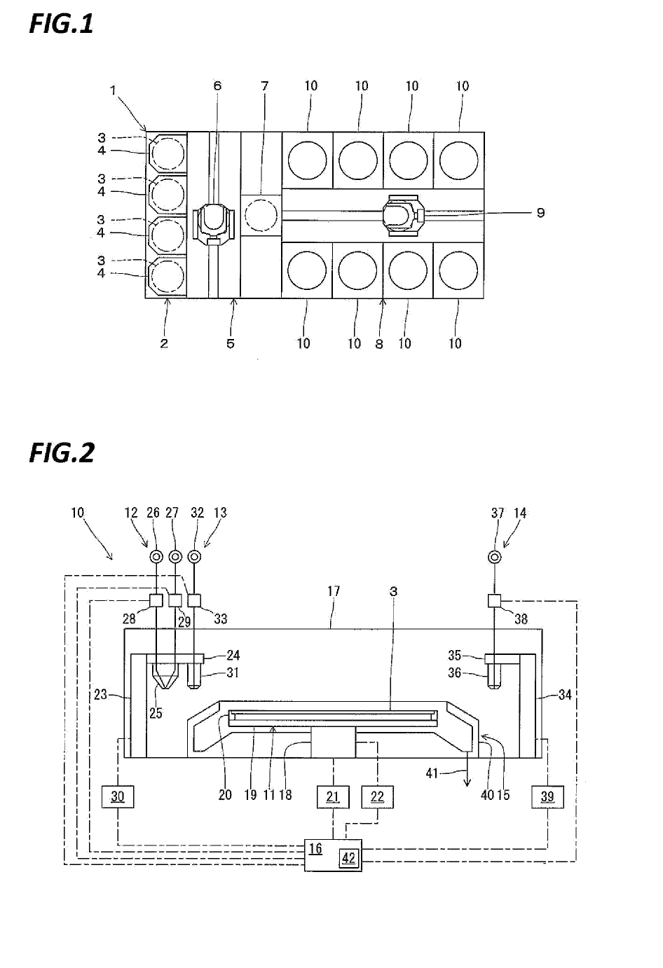

As illustrated in FIG. 1, a liquid processing apparatus 1 includes a carrying-in/out section 2 formed at a front end thereof. Carriers 4 are carried into or out of the carrying-in/out section 2, and are placed to be laterally arranged in the carrying-in/out section 2. Each of the carriers 4 accommodates a plurality of substrates 3 (e.g., 25 substrates) (here, semiconductor wafers).

A conveyance section 5 is formed at the rear side of the carrying-in/out section 2 in the liquid processing apparatus 1. A substrate conveyance device 6 is disposed at the front side of the conveyance section 5, and a substrate delivery unit 7 is disposed at the rear side of the conveyance section 5. In the conveyance section 5, substrates 3 are conveyed between any one of the carriers 4 placed in the carrying-in/out section 2 and the substrate delivery unit 7 by using the substrate conveyance device 6.

A processing section 8 is formed at the rear side of the conveyance section 5 in the liquid processing apparatus 1. A substrate conveyance device 9 is disposed at the central portion of the processing section 8 to extend in a front-rear direction, and substrate processing devices 10 configured to perform a liquid processing on the substrates 3 are disposed at the left and right sides of the substrate conveyance device 9 and arranged in the front-rear direction. In the processing section 8, the substrates 3 are conveyed by using the substrate conveyance device 9 between the substrate delivery unit 7 and the substrate processing devices 10 and are subjected to a liquid processing by using the substrate processing devices 10.

The substrate processing device 10, as illustrated in FIG. 2, includes a substrate holding unit 11 configured to hold and rotate the substrate 3, first to third processing liquid ejecting units 12, 13 and 14 configured to eject processing liquids to the substrate 3, a collecting unit 15 configured to collect the processing liquids, and a control unit 16 configured to control the substrate holding unit 11, the first to third processing liquid ejecting units 12, 13 and 14, and the collecting unit 15.

In the substrate holding unit 11, a rotation shaft 18 which vertically extends is rotatably provided at the substantially central position within a substrate processing container 17. A disk-shaped turn table 19 is horizontally attached to the upper end of the rotation shaft 18. A plurality of substrate holders 20 are attached to the outer periphery of the turn table 19 at equal intervals in the circumferential direction.

In the substrate holding unit 11, a substrate rotation mechanism 21 and a substrate elevating mechanism 22 are connected to the rotation shaft 18. Rotation or elevation of the substrate rotation mechanism 21 and the substrate elevating mechanism 22 is controlled by the control unit 16.

The substrate holding unit 11 horizontally holds the substrate 3 by the substrate holders 20 of the turn table 19. The substrate holding unit 11 rotates the substrate 3 held by the turn table 19 by using the substrate rotation mechanism 21, and moves up and down the turn table 19 or the substrate 3 by using the substrate elevating mechanism 22.

In the first processing liquid ejecting unit 12, a rotation shaft 23 which extends vertically is rotatably provided at the left side of the substrate processing container 17. An arm 24 which extends horizontally is provided at the upper end of the rotation shaft 23. A first processing liquid ejecting nozzle (two-fluid nozzle) 25 is attached to the lower left side of the distal end of the arm 24 to be directed vertically downward. A first processing liquid supply source 26 configured to supply pure water as a first processing liquid and an inert gas supply source 27 configured to supply a nitrogen gas as an inert gas are connected to the first processing liquid ejecting nozzle 25 through flow rate controllers 28 and 29, respectively. Flow rate controls of the flow rate controllers 28 and 29 are performed by the control unit 16. For example, carbon dioxide is added in a small amount to the pure water as the first processing liquid so as to suppress, for example, the substrate 3 from being electrified.

A nozzle moving mechanism 30 is connected to the rotation shaft 23 in the first processing liquid ejecting unit 12. A movement control of the nozzle moving mechanism 30 is performed by the control unit 16.

In the first processing liquid ejecting unit 12, the first processing liquid ejecting nozzle 25 is moved between the position above the center of the substrate 3 (a start position) and the left outside of the substrate 3 (a retreat position) by the nozzle moving mechanism 30, and the first processing liquid is turned into liquid droplets due to the inert gas and sprayed toward the front surface (the top surface) of the substrate 3 by the first processing liquid ejecting nozzle 25.

In the second processing liquid ejecting unit 13, the second processing liquid ejecting nozzle 31 is attached to the lower right side of the distal end of the arm 24 to be directed vertically downward. A second processing liquid supply source 32 configured to supply an SC-1 (Standard Clean 1) liquid (a mixed solution of hydrogen peroxide and ammonium hydroxide) as a second processing liquid is connected to the second processing liquid ejecting nozzle 31 through a flow rate controller 33. A flow control of the flow rate controller 33 is performed by the control unit 16.

In the second processing liquid ejecting unit 13, the second processing liquid ejecting nozzle 31 is moved between a position above the center of the substrate 3 (the start position) and the left outside of the substrate 3 (the retreat position) by the nozzle moving mechanism 30, and the second processing liquid is ejected toward the front surface (the top surface) of the substrate 3 from the second processing liquid ejecting nozzle 31.

In the third processing liquid ejecting unit 14, a rotation shaft 34 which extends vertically is rotatably provided at the right side of the substrate processing container 17. An arm 35 which extends horizontally is provided at the upper end of the rotation shaft 34. A third processing liquid ejecting nozzle 36 is attached to the lower side of the distal end of the arm 35 to be directed vertically downward. A third processing liquid supply source 37 configured to supply pure water as a third processing liquid is connected to the third processing liquid ejecting nozzle 36 through a flow rate controller 38. A flow rate control of the flow rate controller 38 is performed by the control unit 16. An antistatic agent such as, for example, carbon dioxide is added in a small amount to the pure water as the third processing liquid so as to suppress electrification.

A nozzle moving mechanism 39 is connected to the rotation shaft 34 in the third processing liquid ejecting unit 14. A movement control of the nozzle moving mechanism 39 is performed by the control unit 16.

In the third processing liquid ejecting unit 14, the third processing liquid ejecting nozzle 36 is moved between a position above the center of the substrate 3 (the start position) and the right outside of the substrate 3 (the retreat position) by the nozzle moving mechanism 39, and the third processing liquid is ejected toward the front surface (the top surface) of the substrate 3 from the third processing liquid ejecting nozzle 36.

In the collecting unit 15, an annular collecting cup 40 is disposed around the turn table 19. An opening having a much larger size than the turn table 19 is formed at the upper end of the collecting cup 40. A drain 41 is connected to the lower end of the collecting cup 40.

The collecting unit 15 collects the processing liquids supplied to the surface of the substrate 3 by the collecting cup 40 and discharges the liquids from the drain 41 to the outside. The collecting unit 15 may include a plurality of collecting ports formed in the collecting cup 40, and the collecting ports may be varied according to the properties of the processing liquids to be collected (e.g., acidic, neutral or alkaline).

The liquid processing apparatus 1 is configured as described above, and is controlled by the control unit 16 in accordance with various programs recorded in a recording medium 42 provided in the control unit 16 (a computer) to process a substrate 3. Here, the recording medium 42 stores various setting data or programs therein, and is constituted by s, for example, a memory (e.g., a ROM or a RAM), and a disk type recording medium (e.g., a hard disk, a CD-ROM, a DVD-ROM or a flexible disk)) which are known in the related art.

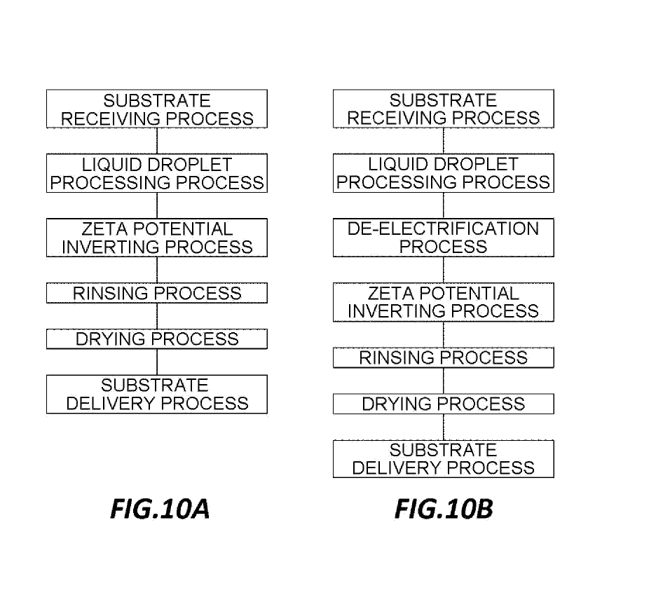

The liquid processing apparatus 1 processes the substrate 3 as described below in accordance with a substrate processing program recorded in the recording medium 42 (see, e.g., FIG. 10A).

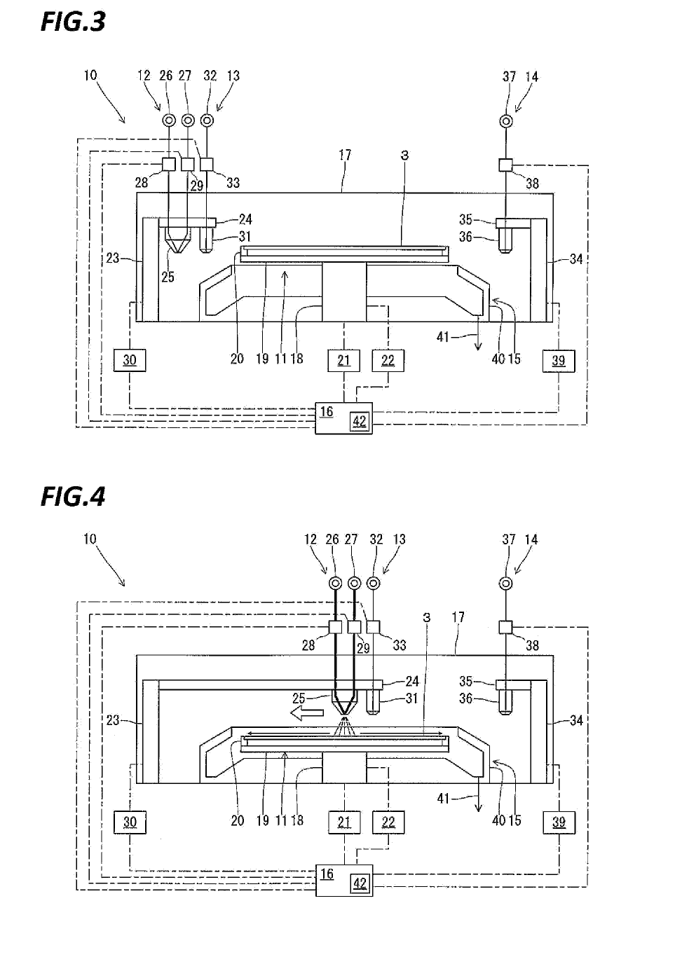

First, in the liquid processing apparatus 1, the substrate 3 conveyed by the substrate conveyance device 9 is received by the substrate processing device 10, as illustrated in FIG. 3 (a substrate receiving process).

In the substrate receiving process, the turn table 19 is moved up to a predetermined position by the substrate elevating mechanism 22. Then, one substrate 3 conveyed from the substrate conveyance device 9 into the substrate processing container 17 is received while the substrate 3 is horizontally held by the substrate holders 20. Then, the turn table 19 is moved down to a predetermined position by the substrate elevating mechanism 22. In the substrate receiving process, the first to third processing liquid ejecting nozzles 25, 31 and 36 are retreated to the retreat position outside of the outer periphery of the turn table 19.

Then, in the liquid processing apparatus 1, as illustrated in FIG. 4, the surface of the substrate 3 is processed by pure water in the form of liquid droplets (including mists) (a liquid droplet processing process).

In the liquid droplet processing process, the arm 24 is moved by the nozzle moving mechanism 30 to move the first processing liquid ejecting nozzle 25 to the supply start position above the center of the substrate 3. Then, pure water at a predetermined flow rate is turned into liquid droplets by a nitrogen gas at a predetermined flow rate and ejected toward the surface of the substrate 3 from the first processing liquid ejecting nozzle 25 by the flow rate controllers 28 and 29. Then, the first processing liquid ejecting nozzle 25 is moved horizontally by the nozzle moving mechanism 30 along the substrate 3 from the position above the center of the substrate 3 toward the left outside. The pure water supplied to the substrate 3 is collected by the collecting cup 40 and discharged from the drain 41 to the outside. After the first processing liquid ejecting nozzle 25 has reached the periphery of the substrate 3, the ejection of the pure water and the nitrogen gas is stopped by the flow rate controllers 28 and 29. At the final stage of the liquid droplet processing process, the arm 24 is moved by the nozzle moving mechanism 30 to move the first processing liquid ejecting nozzle 25 to the retreat position leftward outside of the outer periphery of the substrate 3.

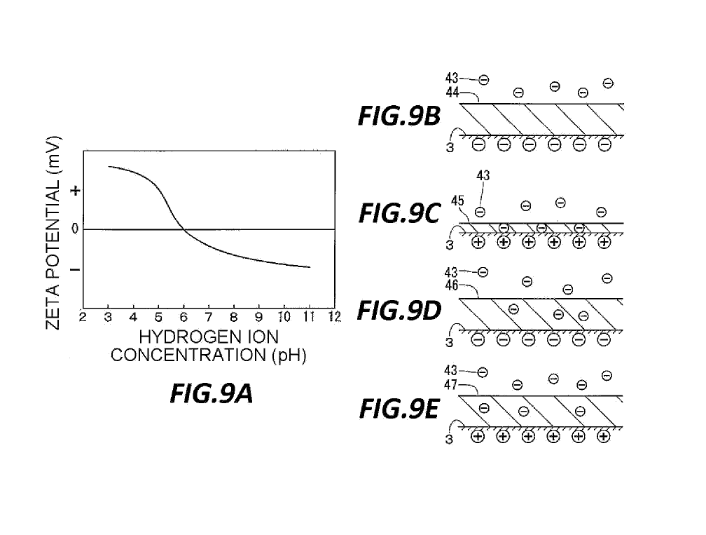

In the liquid droplet processing process, particles which have been attached on the surface of the substrate 3 prior to the processing may be removed. Meanwhile, in the liquid droplet processing process, since the first processing liquid (pure water added with carbon dioxide) is acidic, as schematically illustrated in FIGS. 9A and 9C, the surface of the substrate 3 has a positive zeta potential. Most of particles 43 floating around the substrate 3 within the substrate processing container 17 are negatively electrified, and thus, are attracted to the surface of the substrate 3. Further, since the first processing liquid in the form of liquid droplets is sprayed on the surface of the substrate 3, a liquid film 45 of the pure water is relatively thinly formed on the surface of the substrate 3. Thus, in the liquid droplet processing process, the particles 43 may be easily attached on the surface of the substrate 3 through the liquid film 45 of the pure water with a thin film thickness.

Then, in the liquid processing apparatus 1, as illustrated in FIG. 5, the surface of the substrate 3 is processed by an SC-1 liquid so as to invert the positive zeta potential of the surface of the substrate 3 to a negative zeta potential (a zeta potential inverting process).

In the zeta potential inverting process, the arm 24 is moved by the nozzle moving mechanism 30 to move the second processing liquid ejecting nozzle 31 to the supply start position above the center of the substrate 3. Then, the SC-1 liquid at a predetermined flow rate is ejected toward the center of the surface of the substrate 3 from the second processing liquid ejecting nozzle 31 by the flow rate controller 33. The SC-1 liquid supplied to the substrate 3 is collected by the collecting cup 40 and discharged from the drain 41 to the outside. Then, the ejection of the cleaning liquid is stopped by the flow rate controller 33. At the final stage of the zeta potential inverting process, the arm 24 is moved by the nozzle moving mechanism 30 to move the second processing liquid ejecting nozzle 31 to the retreat position leftward outside of the outer periphery of the substrate 3.

In the zeta potential inverting process, the second processing liquid (the SC-1 liquid) is alkaline. Thus, as schematically illustrated in FIGS. 9A and 9D, the positive zeta potential of the surface of the substrate 3 is inverted into a negative zeta potential when, for example, a silicon nitride film is formed on the surface of the substrate 3. Here, the zeta potential is not immediately inverted but gradually inverted. Thus, at the initial stage of the zeta potential inverting process, the surface of the substrate 3 is positively electrified. However, in the zeta potential inverting process, since a liquid film 46 of the SC-1 liquid is relatively thickly formed on the surface of the substrate 3, the particles 43 in the atmosphere are not attached on the surface of the substrate 3, but are discharged to the outside of the substrate 3 together with the SC-1 liquid. Then, since the surface of the substrate 3 is negatively electrified, the negatively electrified particles 43 may repel each other on the surface of the substrate 3 so that the particles 43 attached on the surface of the substrate 3 may be separated. Accordingly, the particles 43 are suppressed form being attached on the surface of the substrate 3.

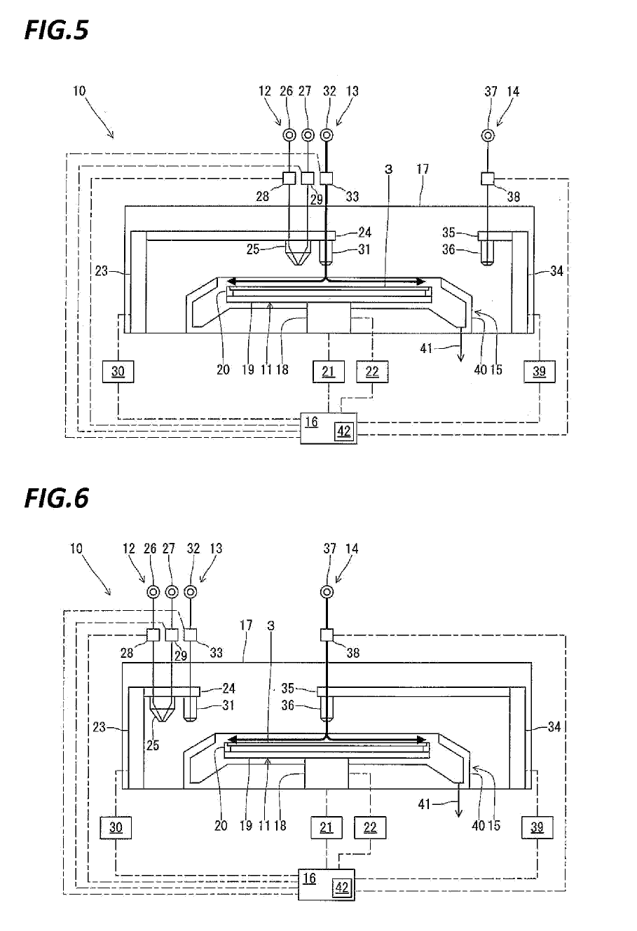

Then, in the liquid processing apparatus 1, as illustrated in FIG. 6, the surface of the substrate 3 is processed by pure water (a rinsing process).

In the rinsing process, the arm 35 is moved by the nozzle moving mechanism 39 to move the third processing liquid ejecting nozzle 36 to the supply start position above the center of the substrate 3. Then, pure water is ejected at a predetermined flow rate toward the center of the surface of the substrate 3 from the third processing liquid ejecting nozzle 36 by the flow rate controller 38. The pure water supplied to the substrate 3 is collected by the collecting cup 40 and discharged from the drain 41 to the outside. At the final stage of the rinsing process, the arm 35 is moved by the nozzle moving mechanism 39 to move the third processing liquid ejecting nozzle 36 to the retreat position rightward outside of the outer periphery of the substrate 3. The ejection of the pure water is stopped by the flow rate controller 38.

In the rinsing process, as schematically illustrated in FIGS. 9A and 9E, since a third processing liquid (pure water added with an antistatic agent such as, for example, carbon dioxide) is acidic, the surface of the substrate 3 has a positive zeta potential. However, since the pure water is supplied to the surface of the substrate 3, a liquid film 47 of the pure water is relatively thickly formed on the surface of the substrate 3. Thus, in the rinsing process, the particles 43 are blocked by the thick liquid film 47 of the pure water and thus, are suppressed from being attached on the surface of the substrate 3.

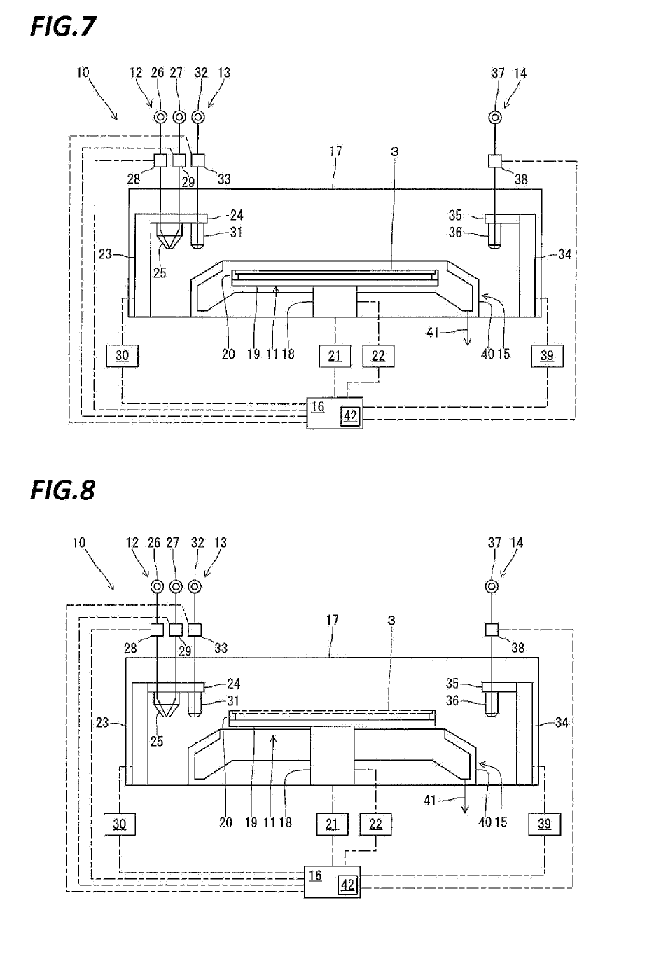

Then, in the liquid processing apparatus 1, as illustrated in FIG. 7, the processing liquid is removed from the surface of the substrate 3 to dry the substrate 3 (a drying process).

In the drying process, the turn table 19 is rotated by the substrate rotation mechanism 21 at a predetermined rotation speed to rotate the substrate 3. Accordingly, the pure water on the surface of the substrate 3 is shaken off by the action of the centrifugal force generated by rotation of the substrate 3 to the outside of the outer periphery of the substrate 3. The pure water shaken off from the surface of the substrate 3 is collected by the collecting cup 40, and discharged from the drain 41 to the outside.

Finally, in the liquid processing apparatus 1, as illustrated in FIG. 8, the substrate 3 is delivered from the substrate processing device 10 to the substrate conveyance device 9 (a substrate delivery process).

In the substrate delivery process, the rotation of the turn table 19 by the substrate rotation mechanism 21 is stopped, and the turn table 19 is moved up to a predetermined position by the substrate elevating mechanism 22. The substrate 3 held by the turn table 19 is delivered to the substrate conveyance device 9. Then, the turn table 19 is moved down to a predetermined position by the substrate elevating mechanism 22.

As described above, in the liquid processing apparatus 1 (the liquid processing method performed in the liquid processing apparatus 1), the surface of the substrate 3 is processed by a first processing liquid in the form of liquid droplets which contains pure water (here, an acidic processing liquid, e.g., pure water added with an antistatic agent such as, for example, carbon dioxide) (a liquid droplet processing process), and then, is processed by a second processing liquid (here, an alkaline processing liquid, e.g., an SC-1 liquid) which inverts the zeta potential of the surface of the substrate 3 to a negative zeta potential (a zeta potential inverting process). Accordingly, in the liquid processing apparatus 1 (the liquid processing method), particles in the atmosphere may be suppressed from being newly attached on the surface of the substrate 3, and attached particles may be removed so that the processing of the substrate 3 may be sufficiently performed.

Here, in the present disclosure, the zeta potential inverting process may be performed after the liquid droplet processing process is performed. However, the present disclosure is not limited to the case in the liquid processing apparatus 1 in which the zeta potential inverting process is performed right after the liquid droplet processing process is performed. For example, when the liquid droplet processing process is performed, static electricity may be generated by friction between liquid droplets or between liquid droplets and a substrate 3 so that the substrate 3 may be electrified. When the substrate 3 is electrified, for example, an alkaline processing liquid (e.g., an SC-1 liquid) to be used in the following process may remain on the surface of the substrate 3, and the electrical property of the substrate 3 may be degraded (e.g., occurrence of leakage current). Therefore, as illustrated in FIG. 10B, a de-electrification process for discharging the electric charges electrified on the substrate 3 may be performed after the liquid droplet processing process before the zeta potential inverting process. In the de-electrification process, an acidic processing liquid may be ejected to the substrate 3 so as to reduce electric charges electrified on the substrate 3, or a rinsing process may be performed by using the pure water added with an antistatic agent such as, for example, carbon dioxide. In this manner, when the de-electrification process is performed after the liquid droplet processing process is performed, and then the zeta potential inverting process is performed, particles may be more sufficiently removed from the surface of the substrate 3. In processings following the liquid droplet processing process, processing liquids are not supplied as liquid droplets, but supplied as continuous liquid streams. That is, each processing liquid ejecting nozzle ejects a processing liquid not as liquid droplets, but as a continuous liquid stream.

In the present disclosure, before the liquid droplet processing process, an SC-1 liquid may be ejected at a predetermined flow rate toward the surface of the substrate 3, and then, the first processing liquid may be ejected in the form of liquid droplets. A predetermined flow rate mentioned herein refers to a flow rate at which a processing liquid may cover the surface of the substrate 3. Accordingly, particles may be separated by the SC-1 liquid from the surface of the substrate 3, and in the following liquid droplet processing process, the particles may be removed from the surface of the substrate 3. The first processing liquid ejecting nozzle 25 is not limited to a two-fluid nozzle as long as it may eject the first processing liquid in the form of liquid droplets. For example, a one-fluid nozzle may be used.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A liquid processing apparatus comprising:
a first processing liquid ejecting unit configured to eject a first processing liquid in a form of liquid droplets which contains pure water toward a surface of a substrate; and
a second processing liquid ejecting unit configured to eject a second processing liquid as a continuous liquid stream toward the surface of the substrate processed by the first processing liquid in the form of the liquid droplets, the second processing liquid inverting a zeta potential on the surface of the substrate into a negative zeta potential.

2. The liquid processing apparatus of claim 1, wherein the second processing liquid ejecting unit ejects the second processing liquid toward the surface of the substrate right after the surface of the substrate is processed by the first processing liquid in the form of the liquid droplets.

3. The liquid processing apparatus of claim 1, further comprising:
an SC-1 liquid ejecting unit configured to eject an SC-1 liquid toward the surface of the substrate,
wherein the first processing liquid ejecting unit ejects the first processing liquid in the form of the liquid droplets after the SC-1 liquid is ejected from the SC-1 liquid ejecting unit toward the surface of the substrate.

4. The liquid processing apparatus of claim 1, wherein pure water added with carbon dioxide is used as the first processing liquid, and an SC-1 liquid is used as the second processing liquid.

5. The liquid processing apparatus of claim 1, wherein, as the substrate, a substrate having a surface formed with a silicon nitride film is used.

6. The liquid processing apparatus of claim 1, further comprising:
a third processing liquid ejecting unit configured to eject a third processing liquid as a continuous liquid stream toward the surface of the substrate processed by the first processing liquid in the form of the liquid droplets, the third processing liquid discharging electric charges electrified on the substrate.

7. The liquid processing apparatus of claim 6, wherein pure water added with carbon dioxide is used as the third processing liquid, and an SC-1 liquid is used as the second processing liquid.

8. A method of performing a liquid processing on a substrate by using a liquid processing apparatus which includes a first processing liquid ejecting unit configured to eject a first processing liquid in a form of liquid droplets which contains pure water toward a surface of the substrate, and a second processing liquid ejecting unit configured to eject a second processing liquid as a continuous liquid stream to the surface of the substrate, the method comprising:
processing the surface of the substrate by the first processing liquid in the form of the liquid droplets which contains the pure water; and
ejecting the second processing liquid from the second processing liquid ejecting unit to the surface of the substrate to process the surface of the substrate, the second processing liquid inverting a zeta potential on the surface of the substrate into a negative zeta potential.

9. The method of claim 8, wherein the surface of the substrate is processed by the second processing liquid right after the surface of the substrate is processed by the first processing liquid in the form of the liquid droplets.

10. The method of claim 8, wherein the surface of the substrate is processed by an SC-1 liquid before the surface of the substrate is processed by the first processing liquid in the form of the liquid droplets.

11. The method of claim 8, wherein pure water added with carbon dioxide is used as the first processing liquid, and an SC-1 liquid is used as the second processing liquid.

12. The method of claim 8, wherein, as the substrate, a substrate having a surface formed with a silicon nitride film is used.

13. The method of claim 8, wherein after the surface of the substrate is processed by the first processing liquid in the form of the liquid droplets, the surface of the substrate is processed by a continuous liquid stream of a third processing liquid, and then is processed by the second processing liquid, the third processing liquid discharging electric charges electrified on the substrate.

14. The method of claim 13, wherein pure water added with carbon dioxide is used as the third processing liquid, and an SC-1 liquid is used as the second processing liquid.

15. The method of claim 14, wherein pure water added with carbon dioxide is used as the first processing liquid, and
wherein the surface of the substrate is processed by an SC-1 liquid before the surface of the substrate is processed by the first processing liquid in the form of the liquid droplets, and the surface of the substrate is processed by pure water added with carbon dioxide as a continuous liquid stream after the surface of the substrate is processed by the first processing liquid in the form of the liquid droplets, and the second processing liquid.
